(19) United States
(12) Patent Application Publication
(10) Pub. No.: US 2007/0279983 A1
(43) Pub. Date: Dec. 6, 2007

(54) SEMICONDUCTOR MEMORY DEVICE AND DATA TRANSMISSION METHOD THEREOF

(76) Inventor: Hiroyuki Nagashima, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/754,574

(22) Filed: May 29, 2007

(30) Foreign Application Priority Data
May 31, 2006 (JP) 2006-152217

(51) Int. Cl. G11C 16/04; G11C 11/34

(52) U.S. Cl. 365/185.04

(57) ABSTRACT

A semiconductor memory device includes a nonvolatile memory which stores protect information, a controller which includes a system buffer and controls a physical state of the nonvolatile memory, a battery which drives the nonvolatile memory and the controller, first transmission/reception means capable of transmitting data in the nonvolatile memory to an outside and receiving data which is transmitted from the outside, and second transmission/reception means capable of transmitting data in the nonvolatile memory to an outside and receiving data which is transmitted from the outside.

### CROSS-REFERENCE TO RELATED APPLICATIONS

This application is based upon and claims the benefit of priority from prior Japanese Patent Application No. 2006-152217, filed May 31, 2006, the entire contents of which are incorporated herein by reference.

### BACKGROUND OF THE INVENTION

1. Field of the Invention

The present invention relates to a semiconductor memory device and a data transmission method of the semiconductor memory device, and the invention is applied to, for example, a USB memory.

2. Description of the Related Art

In recent years, with an increase in capacity of a nonvolatile memory such as a NAND-type flash memory, there has been an increasing demand for portable semiconductor memory devices such as a USB (Universal Serial Bus) memory and a memory card.

The USB memory, for instance, is a memory which is connectable to a USB terminal of a host apparatus such as a PC (Personal Computer) (see, e.g. Jpn. Pat. Appln. KOKAI Publication No. 2006-94441). With currently available USB memories, data write and data erase can be executed as a matter of course. However, data transmission, such as data transfer/data exchange, cannot be executed between the USB memories.

For example, in a case where music information, or a work, on a Web has lawfully been purchased and downloaded in a PC, etc., it is considered that the right of duplication has been extinguished. On the other hand, a transfer right, which is another copyright/property right of the music information, still remains on the music information that is the original work. Thus, in the case where the music information, which is stored in the USB memory from the PC, is transferred to a third person, an infringement on the copyright, such as the transfer right, is formally constituted.

Furthermore, if a trade secret or the like is included in such transmission data, an act of unfair competition may be constituted in some cases.

On the other hand, there is no technical means which can avoid a problem of copyright, etc., with respect to data that is transmitted between conventional memory media. Hence, data in memory media, such as music information, photos and video, cannot easily be transmitted between the memory media, and the convenience for use is low.

### BRIEF SUMMARY OF THE INVENTION

According to an aspect of the present invention, there is provided a semiconductor memory device comprising: a nonvolatile memory which stores protect information; a controller which includes a system buffer and controls a physical state of the nonvolatile memory; a battery which drives the nonvolatile memory and the controller; first transmission/reception means capable of transmitting data in the nonvolatile memory to an outside and receiving data which is transmitted from the outside; and second transmission/reception means capable of transmitting data in the nonvolatile memory to an outside and receiving data which is transmitted from the outside.

According to another aspect of the present invention, there is provided a data transmission method for a semiconductor memory device comprising: a first semiconductor memory device including a first nonvolatile memory which stores protect information, a first controller which includes a first system buffer and controls a physical state of the first nonvolatile memory, a battery which drives the first nonvolatile memory and the first controller, and first transmission/reception means capable of transmitting data in the first nonvolatile memory to an outside and receiving data which is transmitted from the outside, and second transmission/reception means capable of transmitting data in the first nonvolatile memory to an outside and receiving data which is transmitted from the outside; and a second semiconductor memory device including a second nonvolatile memory, a second controller which includes a second system buffer and controls a physical state of the second nonvolatile memory, and third transmission/reception means capable of transmitting data in the second nonvolatile memory to an outside and receiving data which is transmitted from the outside, the data transmission method comprising: electrically connecting one of the first transmission/reception means and the second transmission/reception means to the third transmission/reception means; causing the first controller to read out transmission data from the first nonvolatile memory; and causing the first controller not to transmit transmission data with the protection information, which is included in the transmission data, to the second semiconductor memory device.

### BRIEF DESCRIPTION OF THE SEVERAL VIEWS OF THE DRAWING

FIG. 1 is a perspective view showing a semiconductor memory device according to a first embodiment of the present invention;

FIG. 2 is a plan view of a USB receiving terminal;

FIG. 3 is a block diagram of the semiconductor memory device according to the first embodiment;

FIG. 4 is a perspective view for explaining a data transfer operation according to the first embodiment;

FIG. 5 is a block diagram for explaining the data transfer operation according to the first embodiment;

FIG. 6 is a flow chart for illustrating the data transfer operation according to the first embodiment;

FIG. 7 is a plan view for describing transmission data at a time of a protect check;

FIG. 8 is a plan view for describing a data exchange operation of the semiconductor memory device according to the first embodiment;

FIG. 9 is a timing chart illustrating the data exchange operation of the semiconductor memory device according to the first embodiment;

FIG. 10 is a perspective view showing a semiconductor memory device according to a second embodiment of the present invention; and

FIG. 11 is a perspective view for explaining a data transfer operation of the semiconductor memory device according to the second embodiment.

### DETAILED DESCRIPTION OF THE INVENTION

Embodiments of the present invention will now be described with reference to the accompanying drawings. In the description below, common parts are denoted by like reference numerals throughout the drawings.

### First Embodiment

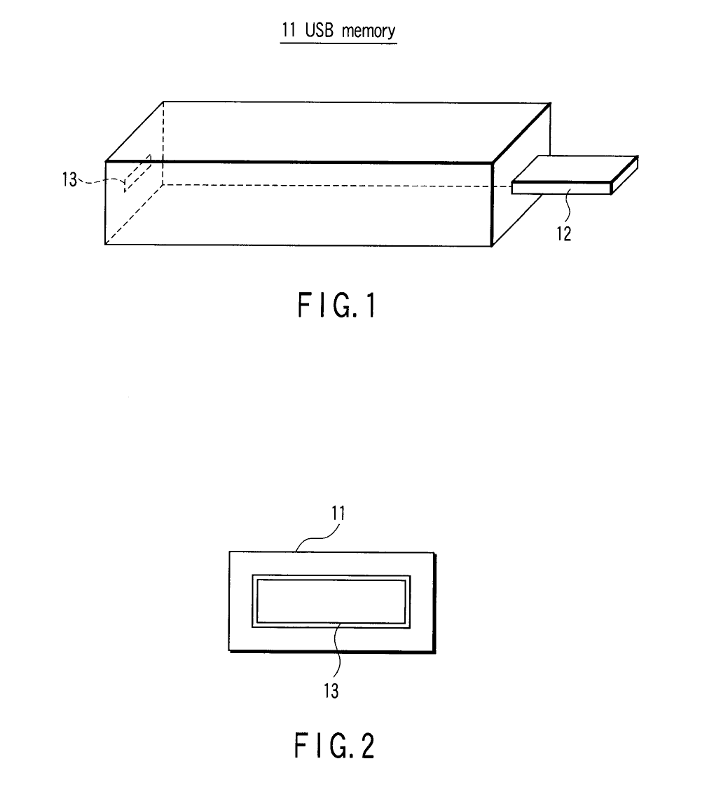

To begin with, referring to FIG. 1 to FIG. 3, a semiconductor memory device according to a first embodiment of the invention is described. FIG. 1 is a perspective view showing the semiconductor memory device according to this embodiment. FIG. 2 is a plan view of a USB receiving terminal. In this embodiment, a USB memory is described by way of example.

As shown in the Figures, the USB memory 11 includes a USB insertion terminal (first transmission/reception means) 12 and a USB reception terminal (second transmission/reception means) 13.

The USB insertion terminal 12 is inserted in and connected to a host apparatus such as a PC (Personal Computer). Thereby, transmission/reception of data in the USB memory 11 is executed.

A USB insertion terminal of another USB memory or the like is inserted in and connected to the USB reception terminal 13. Thereby, transmission/reception of data in the USB memory 11 is executed.

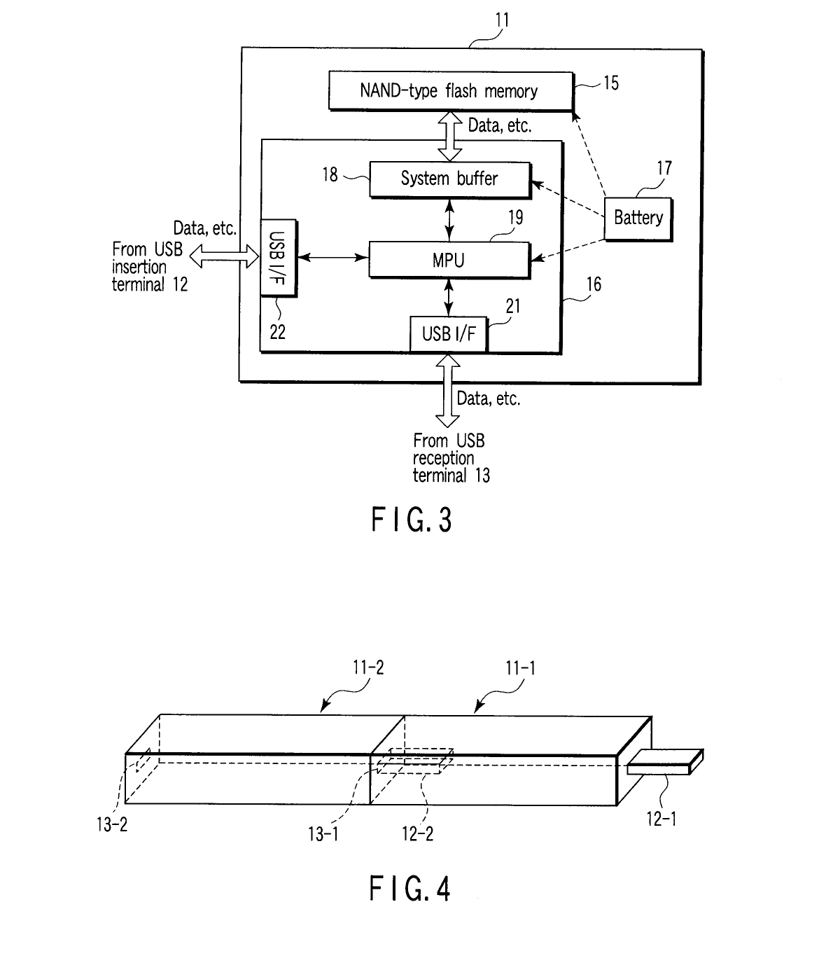

Next, the USB memory 11 of this embodiment is described in greater detail with reference to FIG. 3. FIG. 3 is a block diagram of the semiconductor memory device according to this embodiment.

As shown in FIG. 3, the USB memory 11 includes a NAND-type flash memory 15, a controller 16 and a battery 17.

The NAND-type flash memory 15 is a writable/readable nonvolatile memory, and stores data such as music information. The NAND-type flash memory 15 includes a sense amplifier (not shown) having two data caches, and amplifies and reads out stored data by the sense amplifier.

The controller 16 is configured to control the physical state in the NAND-type flash memory 15 (e.g. which of numerically ordered logical sector address data is stored at which physical block address, or which block is in an erased state). In addition, the controller 16 executes a data input/output control and data management for the NAND-type flash memory 15, and adds an error correcting code (ECC) at a time of data write and analyzes/processes the error correcting code (ECC) at a time of data read-out.

The controller 16 includes a system buffer 18, an MPU (Micro-Processing Unit) 19 and USB interfaces (hereinafter referred to as “USB I/F”) 21, 22.

The system buffer 18 is configured to temporarily store data, etc. from the NAND-type flash memory 15.

The MPU 19 is configured to control the operations of the NAND-type flash memory 15 and system buffer 18. For example, the MPU 19 receives a write command, a read command and an erase command from a host apparatus (not shown), and executes a predetermined process for the NAND-type flash memory 15 and controls a data transfer process through the system buffer 18.

The USB I/F 21 is electrically connected to the USB reception terminal 13. Data transmission/reception with another USB memory, for instance, is executed via the USB I/F 21.

The USB I/F 22 is electrically connected to the USB insertion terminal 12. Data transmission/reception with a host apparatus, such as a PC, is executed via the USB I/F 22.

The battery 17 supplies predetermined power to the NAND-type flash memory 15 and controller 16, thereby driving these components. The battery 17 may be configured to be supplied with external power or to be charged with power supplied from outside.

### <Data Transfer Operation>

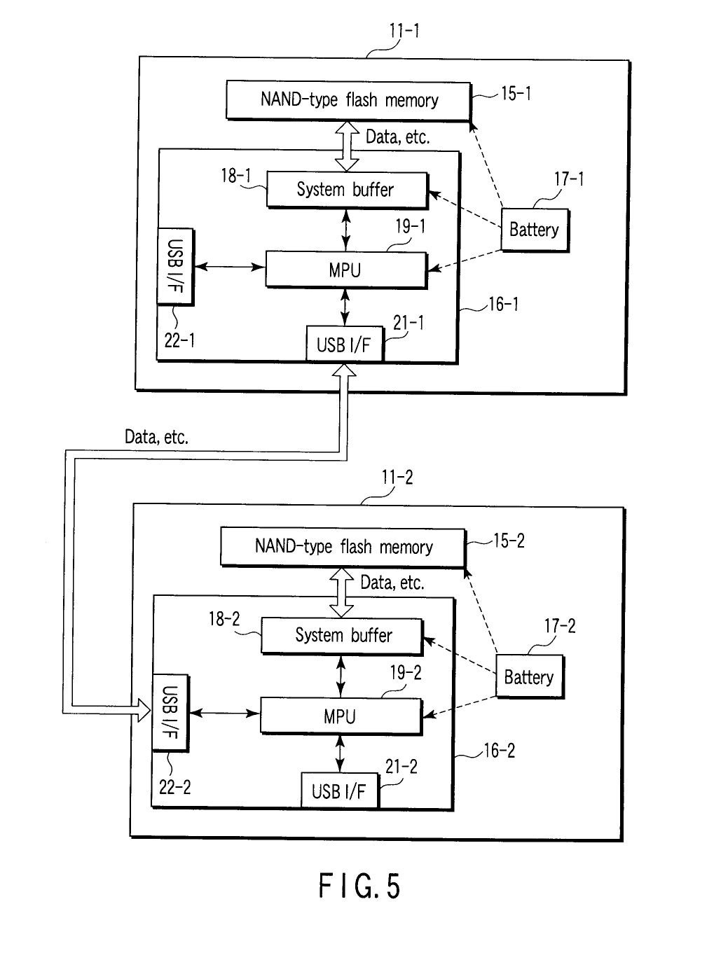

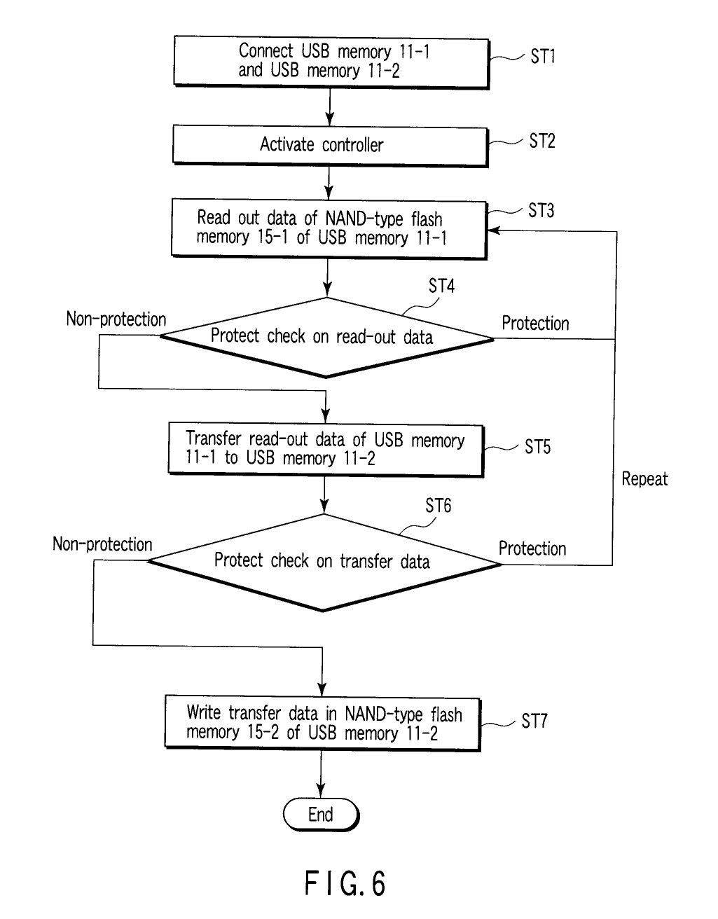

Next, a data transfer operation, which is one of data transmission operations, according the semiconductor memory device of this embodiment is described with reference to FIG. 4 to FIG. 7. FIG. 4 and FIG. 5 are a perspective view and a block diagram for explaining the data transfer operation according to this example. FIG. 6 is a flow chart illustrating the data transfer operation according to this example. In this example, data in a USB memory 11-1, which has the same structure as described in connection with the present embodiment, is transmitted to a USB memory 11-2. The data transfer operation of this example is described with reference to FIG. 6.

### (Step 1)

To start with, as shown in FIG. 4, a USB insertion terminal 12-2 of the USB memory 11-2 is connected to a USB reception terminal 13-1 of the USB memory 11-1. At this time, as shown in FIG. 5, a USB I/F 21-1 of the USB memory 11-1 and a USB I/F 22-2 of the USB memory 11-2 are electrically connected. The USB memories 11-1 and 11-2 are thus connected so that information may be read from each other (ST1).

### (Step 2)

Upon detecting the connection between the USB memories 11-1 and 11-2, MPUs 19-1 and 19-2 activate controllers 16-1 and 16-2. Thereby, NAND-type flash memories 15-1 and 15-2 are rendered operable (ST2).

### (Step 3)

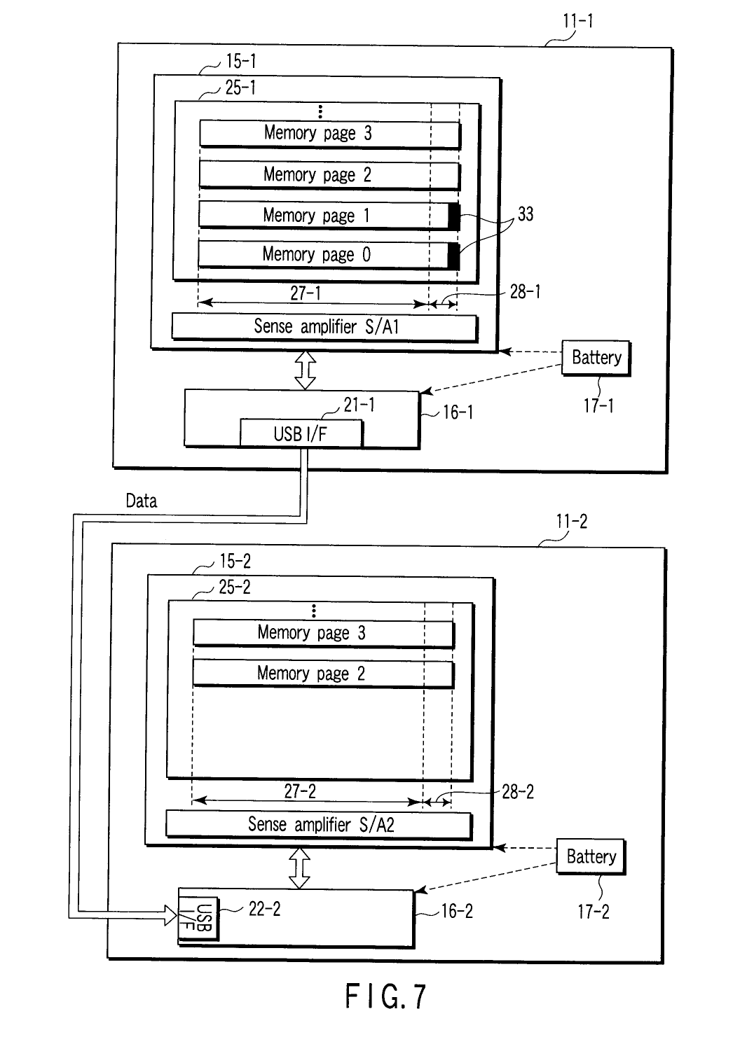

Subsequently, as shown in FIG. 7, transmission data is amplified and read out by a sense amplifier S/A 1 from a NAND-type flash memory 15-1 of the transmission-side USB memory 11-1 (ST3).

### (Step 4 (Protect Check on Transmission Data))

Then, a protect check on the read-out transmission data is executed (ST4).

The protect check will now be explained with reference to FIG. 7. FIG. 7 is a plan view for explaining transmission data at a time of the protect check (ST4). As shown in FIG. 7, the NAND-type flash memory 15-1, 15-2 includes a block 25-1, 25-2 including a plurality of memory pages (in this example, memory page 0 to memory page 3 are shown) which are unit memory areas.

Each of the memory page 0 to memory page 3 includes a data area 27-1, 27-2 and a redundant area 28-1, 28-2. In the case of this example, the capacity of the data area 27-1, 27-2 is about 2000 Bytes, and the capacity of the redundant area 28-1, 28-2 is about 60 Bytes. The above-described error correcting code (ECC) of, e.g. 40 Bytes is stored in the redundant area 27-1, 27-2 (not illustrated). A protect flag (protect information) 33 is included in the redundant area 28-1 of each of the memory page 0 and memory page 1.

When data is to be written in the memory page of the NAND-type flash memory 15-1, the protect flag 33 is selectively written in advance for the data that is to be protected or copy-guarded.

In the case of this example, of the read-out memory pages 0 to 3, the memory page 0 and memory page 1 have protect flags 33. Thus, the controller 16-1 determines that the data in the memory page 0 and memory page 1 are to be protected, does not transfer these data to the USB memory 11-2, and executes a read-out operation for the next memory page 2.

In this example, the protect flag (protect information) 33 is written in the redundant area 28-1. however, the protect information may not be written in the redundant area 28-1, but may be written in the unit of each block 25-1, or in the unit of a file for which data transfer is to be executed.

### (Step 5)

Subsequently, the controller 16-1 transfers the data of the memory page, in which the protect flag 33 is not set, to the USB memory 11-2 (ST5).

For example, the controller 16-1 reads out the memory page 2 (ST3), confirms that no protect flag is set (ST4), and transfers the data of this memory page 2 to the block 25-2 of the USB memory 11-2 (ST5).

Then, the step 3 to step 5 (ST3 to ST5) are similarly repeated for the memory page 3. Subsequently, the step 3 to step 5 (ST3 to ST5) are repeated for all transmission data in the block 25-1, and transfer data is copied.

### (Step 6 (Protect Check on Transfer Data))

The controller 16-2 then executes a protect check on the transferred memory page 2, memory page 3, (ST6).

Specifically, the controller 16-2 confirms once again whether the protect flag 33 is set in the transfer data. At this time, if the controller 16-2 has confirmed that the protect flag 33 is set in the transferred memory page, the controller 16-2 does not execute write of the memory page in the NAND-type flash memory 15-2. Then, the step 3 to step 6 (ST3 to ST6) are repeated.

### (Step 7)

Subsequently, the controller 16-2 writes the data of the memory page 2, etc., in which non-setting of the protect flag 33 has been confirmed, in the NAND-type flash memory 15-2 of the reception-side USB memory 11-2 (ST7).

By the above-described step 1 to step 7, the data transfer operation according to this example is completed.

### <Data Exchange Operation>

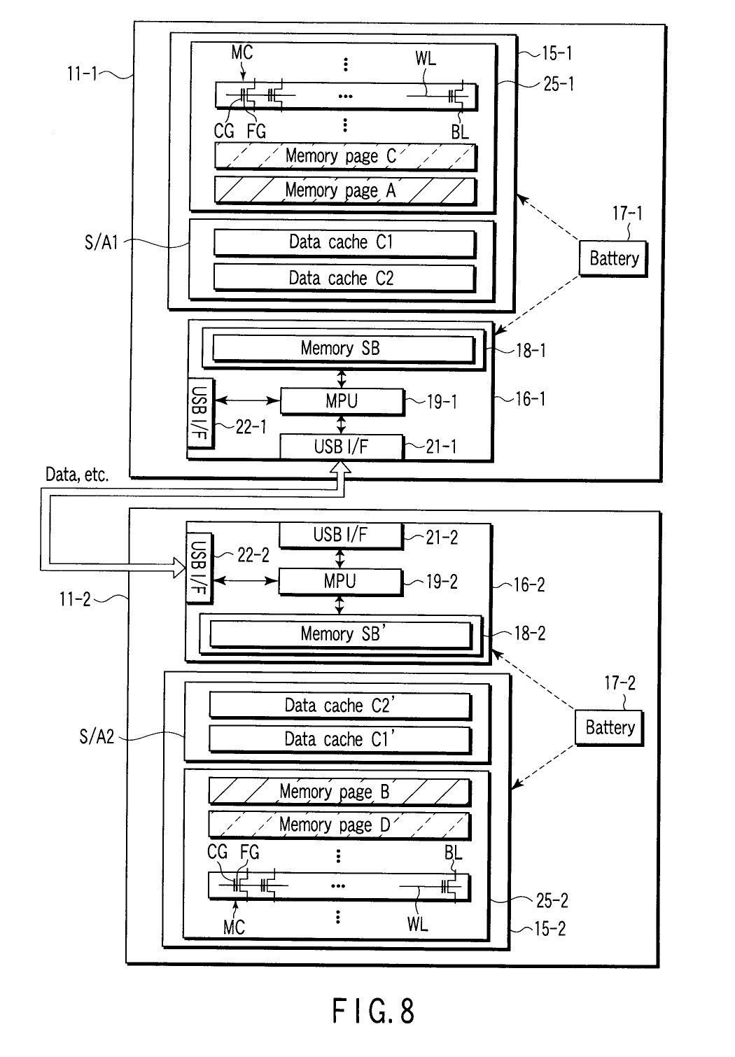

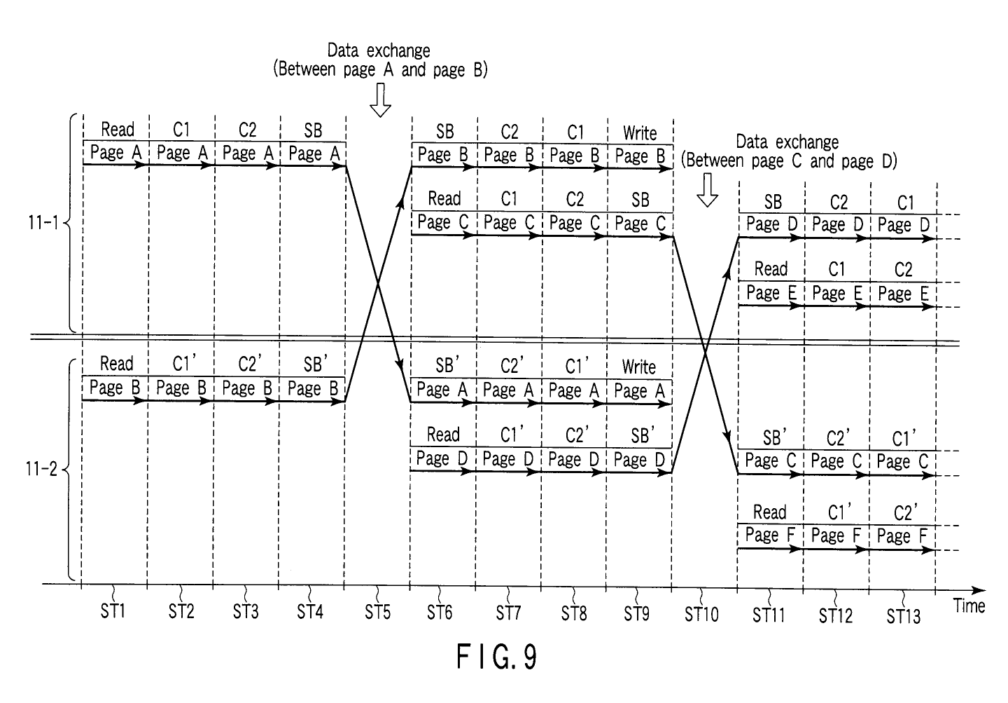

Next, a data exchange operation, which is one of the data transmission operations of the semiconductor memory device according to the present embodiment, is described with reference to FIG. 8 and FIG. 9. FIG. 8 is a block diagram for describing the data exchange operation according to this example. FIG. 9 is a timing chart illustrating the data exchange operation according to this example.

To begin with, referring to FIG. 8, the structure relating to the data exchange of this example is described. As shown in FIG. 8, the USB memory 11-1, 11-2 includes a plurality of memory pages A, B, . . . , as described above.

Each of the memory pages A, . . . , is composed of a plurality of memory cells MC, which are arrayed in a matrix at intersections of word lines WL and bit lines BL. Each of the memory cells MC has a stacked structure comprising a tunnel insulation film provided on a semiconductor substrate, a floating electrode FG provided on the tunnel insulation film, an inter-gate insulation film provided on the floating electrode FG, and a control electrode CG provided on the inter-gate insulation film. Memory cells MC, which neighbor in the direction of the bit line BL, share their sources/drains which constitute current paths. For example, 32 current paths are connected in series at one and the other ends thereof.

The sense amplifier S/A 1, S/A 2 includes two data caches C1 & C2, C1′ & C2′. The sense amplifier S/A 1, S/A 2 is configured such that data of one memory page A, . . . , is stored in one data cache C1, C2, C1′, C2′.

A system buffer 18-1, 18-2 includes a memory SB, SB′, which is composed of, e.g. an SRAM (Static Random-Access Memory). The memory SB, SB′ is configured such that data of one memory page, e.g. memory page A, is stored in one memory SB, SB′.

Next, the data exchange method according to this example is explained with reference to FIG. 9. The USB memories 11-1 and 11-2 having the same structure as described in the present embodiment are taken as examples, and the memory page A and memory page B are exchanged and similarly the memory page C and memory page D are exchanged.

### (Step 1)

To start with, like the data transfer operation, the USB insertion terminal 12-2 of the USB memory 11-2 is connected to the USB reception terminal 13-1 of the USB memory 11-1. At this time, the USB I/F 21-1 of the USB memory 11-1 is electrically connected to the USB I/F 22-2 of the USB memory 11-2. In this manner, the USB memories 11-1 and 11-2 are connected so that information can be read from each other.

The NAND-type flash memories 15-1 and 15-2 of the USB memories 11-1 and 11-2 read out the memory page A and memory page B, respectively (ST1).

At this time, like the above-described transfer operation, the controllers 16-1 and 16-2 execute protect checks as to whether protect flags (protect information) are set in the read-out memory page A and memory page B which are to be exchanged. In the case where the protect flag is set in the memory page A, B, the controller 16-1, 16-2 executes a read operation for the next memory page. In the case of this example, since neither the memory page A nor memory page B has a protect flag, the read operation for the next memory page is not executed.

### (Step 2)

Subsequently, the controller 16-1 stores the data of the read-out memory page A in the data cache C1 in the sense amplifier S/A 1, and the controller 16-2 stores the data of the read-out memory page B in the data cache C1′ in the sense amplifier S/A 2 (ST2).

### (Step 3)

In the following step, the controller 16-1 stores the data of the read-out memory page A in the data cache C2 in the sense amplifier S/A 1, and the controller 16-2 stores the data of the read-out memory page B in the data cache C2′ in the sense amplifier S/A 2 (ST3).

### (Step 4)

The controller 16-1 then stores the data of the read-out memory page A in the memory SB in the system buffer 18-1, and the controller 16-2 stores the data of the read-out memory page B in the memory SB′ in the system buffer 18-2 (ST4).

### (Step 5 (Data Exchange Between Memory Page a and Memory Page B))

The controller 16-1 transfers the data of the memory page A to the USB memory 11-2 via the sub I/F 21-1, and the controller 16-2 transfers the data of the memory page B to the USB memory 11-1 via the USB I/F 22-2. Thus, data exchange is executed at the same time (ST5).

### (Step 6)

Then, the controller 16-1 stores the data of the exchanged memory page B in the memory SB in the system buffer 18-1, and the controller 16-2 stores the data of the exchanged memory page A in the memory SB′ in the system buffer 18-2.

Further, at this time, the controllers 16-1 and 16-2 read out the memory page C and memory page D in the NAND-type flash memories 15-1 and 15-2, which are to be next exchanged (ST6).

### (Step 7)

Subsequently, the controller 16-1 stores the data of the exchanged memory page B in the data cache C2 in the sense amplifier S/A 1, and the controller 16-2 stores the data of the exchanged memory page A in the data cache C2′ in the sense amplifier S/A 2.

At this time, the controller 16-1 stores the data of the to-be-next-exchanged memory page C in the data cache C1 in the sense amplifier S/A 1, and the controller 16-2 stores the data of the memory page D in the data cache C1′ in the sense amplifier S/A 2 (ST7).

### (Step 8)

The controller 16-1 stores the data of the exchanged memory page B in the data cache C1 in the sense amplifier S/A 1, and the controller 16-2 stores the data of the exchanged memory page A in the data cache C1′ in the sense amplifier S/A 2.

At this time, the controller 16-1 stores the data of the to-be-next-exchanged memory page C in the data cache C2 in the sense amplifier S/A 1, and the controller 16-2 stores the data of the memory page D in the data cache C2′ in the sense amplifier S/A 2 (ST8).

### (Step 9)

Subsequently, the controller 16-1 writes the data of the exchanged memory page B in the block 25-1 of the NAND-type flash memory 15-1, and the controller 16-2 writes the data of the exchanged memory page A in the block 25-2 of the NAND-type flash memory 15-2. By the above-described process, the exchange operation between the memory page A and memory page B is completed.

In this case, the controllers 16-1 and 16-2 may execute protect checks once again on the exchanged memory page A and memory page B. Specifically, the controller 16-1, 16-2 confirms once again whether the protect flag is set in the exchanged data. If the controller 16-1, 16-2 confirms that the protect flag is set in the exchanged memory page A, B, the controller 16-1, 16-2 does not execute data write of this memory page in the NAND-type flash memory 15-1, 15-2.

Further, at this time, the controller 16-1 stores the data of the to-be-next-exchanged memory page C in the memory SB in the system buffer 18-1, and the controller 16-2 stores the data of the to-be-next-exchanged memory page D in the memory SB′ in the system buffer 18-2 (ST9).

### (Step 10 (Data Exchange Between Memory Page C and Memory Page D))

The controller 16-1 transfers the data of the memory page C to the USB memory 11-2 via the sub I/F 21-1, and the controller 16-2 transfers the data of the memory page D to the USB memory 11-1 via the USB I/F 22-2. Thus, data exchange is executed at the same time (ST10).

### (Step 11)

Then, the controller 16-1 stores the data of the exchanged memory page D in the memory SB in the system buffer 18-1, and the controller 16-2 stores the data of the exchanged memory page C in the memory SB′ in the system buffer 18-2.

At this time, in like manner, the controllers 16-1 and 16-2 read out a memory page E and a memory page F in the NAND-type flash memories 15-1 and 15-2, which are to be next exchanged (ST1).

Subsequently, similar processes are executed for all the to-be-exchanged memory pages in the NAND-type flash memories 15-1 and 15-2 of the USB memories 11-1 and 11-2, and the data exchange operation is completed.

In this example, data is simultaneously exchanged between the USB memories 11-1 and 11-2. However, for example, in step ST5, one-way transfer of only the data of the memory page A may be executed from the USB memory 11-1 to the USB memory 11-2, or one-way transfer of only the data of the memory page B may be executed from the USB memory 11-2 to the USB memory 11-1. In this case, the controller 16 may be configured to be able to execute such one-way data transfer.

As has been described above, according to the semiconductor memory device and data transmission method of the present embodiment, the following advantageous effects (1) to (3) can be obtained.

### (1) Data can easily be transferred, and the convenience for use can be improved.

As described above, the semiconductor memory device according to this embodiment includes the USB reception terminal 13. Thus, at the time of the data exchange operation, the USB I/F 21-1, which is electrically connected to the USB reception terminal 13, is electrically connected to the USB I/F 22-2 of the USB memory 11-2.

Since the USB memories 11-1 and 11-2 can be mutually connected, information can be read from each other (ST1). Accordingly, the data (memory page 2, memory page 3, . . . ) in the USB memory 11-1 can easily be transferred and exchanged. As a result, the convenience for use can be improved.

Further, the protect flag (protect information) 33 is included in the redundant area 27 of the memory page that is the unit memory area in the NAND-type flash memory 15.

Thus, when data is to be transferred and exchanged from the USB memory 11-1 to the USB memory 11-2, the transmission-side controller 16-1 can execute a protect check to determine whether the protect flag 33 is set for the transmission data (ST4). The controller 16-1 transfers the data of the memory page, for which the protect flag 33 is not set, and does not transfer the data of the memory page, for which the protect flag 33 is set (ST5).

This protect flag 33 is selectively set in advance in the memory page which is to be copy-guarded, when the data is to be written in the transfer-side memory page.

As a result, data with a copyright, a trade secret, etc. is not transferred selectively, and a problem of, e.g. copyright infringement can be prevented from arising (“copy guard”). Moreover, easy data transmission is enabled, and the convenience for use is improved.

The USB memory 11 includes the battery 17 that supplies predetermined power to the NAND-type flash memory 15 and controller 16 and drives these components.

Accordingly, there is no need to connect the USB memory 11 to the host apparatus, such as a PC, and to drive the USB memory 11 together with the host apparatus. The USB memory 11 can be driven independently. Therefore, the USB memory 11 can independently drive the NAND-type flash memory 15. Even in the case where the USB memory 11 is not supplied with power from the host apparatus, data transmission can easily be executed between USB memories 11.

With the above-described structures, data transmission can easily be executed, and the convenience for use can be improved. Hence, music information or the like in a digital audio player, which is possessed by some other person, can easily be transferred or exchanged with that person without intervention of a PC, etc.

### (2) The copy guard function can be enhanced.

As described above, the controller 16-2, which has received transmission data, confirms once again whether the protect flag 33 is set in the transferred and exchanged memory page 2, memory page 3, . . . , and writes the data of the memory page 2, etc., in which the protect flag 33 is not set, in the NAND-type flash memory 15-2 of the transfer-side USB memory 11-2 (ST6). At this time, if the controller 16-2 has confirmed that the protect flag 33 is set in the transferred memory page, the controller 16-2 does not write the data of this memory page in the NAND-type flash memory 15-2.

As described above, the protect check can be executed once again when the transmitted data is to be written. Therefore, even if there is data that has erroneously passed through the protection check (ST4) at the time of transmission, the data can successfully be found by the next protect check (ST6) at the time of data write, and the copy guard function can be enhanced.

### (3) The data exchange speed can be increased.

In the above-described steps 6 to 9 of the data exchange operation, the controller 16-1 stores and writes the data of the exchanged memory page B successively in the memory SB, in the data cache C2 and in the data cache C1. At the same time, the controller 16-1 successively reads out the data of the memory page C that is to be next exchanged, and stores it in the data cache C1, data cache C2 and memory SB.

Similarly, the controller 16-2 stores and writes the data of the exchanged memory page A successively in the memory SB′, in the data cache C2′ and in the data cache C1′. At the same time, the controller 16-2 successively reads out the data of the memory page D that is to be next exchanged, and stores it in the data cache C1′, data cache C2′ and memory SB′ (ST6 to ST9).

As described above, the controller 16-1 stores and writes the exchanged memory page B and at the time same reads out and stores the memory page C that is to be next exchanged. Similarly, the controller 16-2 stores and writes the exchanged memory page A and at the time same reads out and stores the memory page D that is to be next exchanged.

Thus, the time for reading out and storing the to-be-next-exchanged memory page C and memory page D overlaps with the time for storing and writing the memory pages B and A, and a length of time, which corresponds to the time for reading out and storing the to-be-next-exchanged memory page C and memory page D, can be saved.

As a result, immediately after the completion of the data write of the exchanged memory page A and memory page B (ST9), the to-be-next-exchanged memory page C and memory page D can be exchanged (ST10) and the data exchange speed can be increased.

### Second Embodiment (Example of Infrared Transmission)

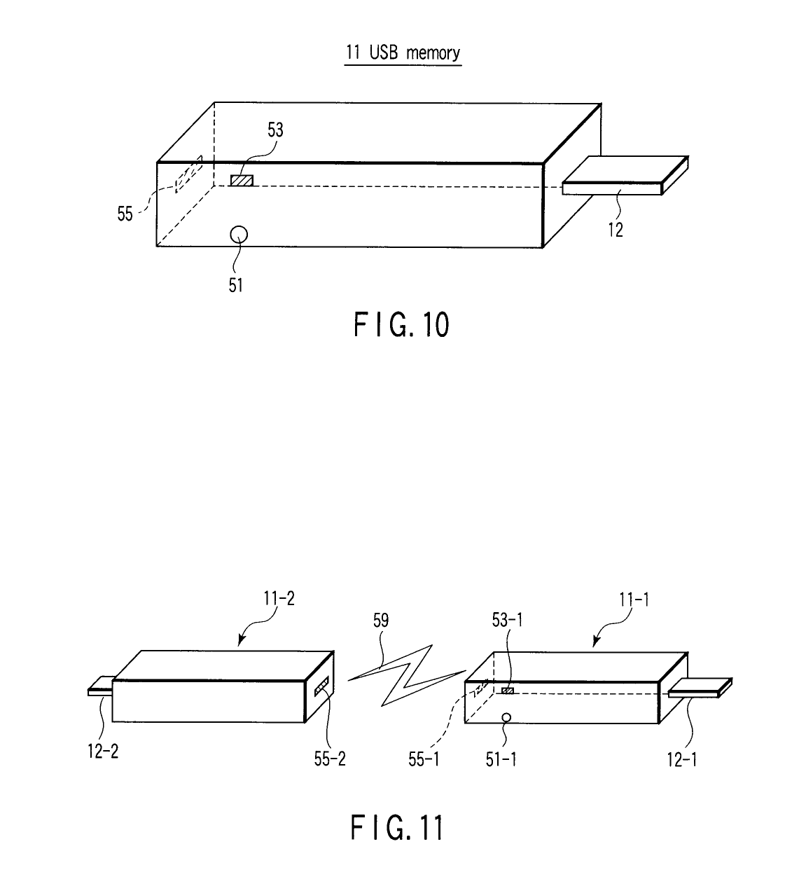

Next, referring to FIG. 10 and FIG. 11, a description is given of a semiconductor memory device according to a second embodiment of the invention and a data transmission method thereof. FIG. 10 is a perspective view of the semiconductor memory device according to this embodiment. In the first embodiment, data transfer and exchange are executed by the connection between the USB terminals 12 and 13. By contrast, in the second embodiment, infrared transmission is used as a method of data transmission. In the description below, a detailed description of the parts common to those in the first embodiment is omitted.

As shown in FIG. 10 and FIG. 11, the second embodiment differs from the first embodiment in that the USB memory 11 of the second embodiment includes a switch 53, an indicator 51 and an infrared port 55.

When the above-described data transfer operation and data exchange operation are to be performed, the switch 53 determines whether the data transfer and data exchange are executed or not. For example, when the switch 53 is in the ON state, the data transfer cannot be executed, and when the switch 53 is in the OFF state, the data transfer can be executed.

The indicator 51 is provided in order to indicate to the outside that the data transfer operation and data exchange operation are being executed. For example, the indicator 51 is composed of, e.g. a light-emitting diode, and the indicator 51 is configured to emit light while the data transfer operation is being performed.

The infrared port 55 is configured to transfer and exchange data in the USB memory 11. In the other structural aspects, the second embodiment is the same as the first embodiment.

### <Data Transfer Operation and Data Exchange Operation>

Next, referring to FIG. 11, a description is given of the data transfer operation and data exchange operation of the semiconductor memory device according to the present embodiment.

As shown in FIG. 11, when the data transfer operation and data exchange operation are performed, the USB memories 11-1 and 11-2 are positioned close to each other at a predetermined distance, and the switch 53-1 is turned on. Infrared 59, to which data has been converted, is radiated between the infrared ports 55-1 and 55-2. During the data transfer operation and data exchange operation, the indicator 51-1 emits light and indicates to the outside that the data transfer operation and data exchange operation are being executed.

Subsequently, in the same manner as in the first embodiment, the data transfer operation and data exchange operation are carried out. If the data transfer operation and data exchange operation are completed, the indicator 51-1 stops emitting light.

As has been described above, according to the semiconductor memory device of this embodiment, the same advantageous effects as in the above-described (1) to (3) can be obtained.

Furthermore, the semiconductor memory device according to this embodiment can directly execute data transfer and exchange between the USB memories 11-1 and 11-2 by using infrared communication.

Since data transfer and exchange can directly be executed without intervention of another device such as a reader/writer, the convenience for use can advantageously be enhanced.

The transmission/reception means is not limited to the infrared port 55. For example, wireless LAN, can be used as transmission/reception means.

In the first and second embodiments, each of the USB memories 11-1 and 11-2 includes the battery 17-1, 17-2. However, if power can be mutually supplied via the USB I/F, etc., only one of the USB memories 11-1 and 11-2 may be equipped with the battery 17.

In the above-described embodiments, bidirectional data transfer and exchange are executed between the USB memories 11-1 and 11-2. However, it is possible to execute one-way data transfer, for example, from the USB memory 11-1 to the USB memory 11-2. In this case, the controller 16 may be configured to enable such one-way data transfer. Whether or not to enable such one-way data transfer may be selectively determined from the standpoint of the convenience for users.

Besides, in the above-described embodiments, the USB memory 11 is described as an example of the semiconductor memory device. However, the invention is applicable to other semiconductor memory devices which enable transfer or exchange of data of a memory card, a mobile phone, etc. In the case of using, for instance, the mobile phone that has a display, it is possible to confirm transfer data on the display, and there is an advantage that the transfer data can be chosen more specifically.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a nonvolatile memory which stores protect information;
a controller which includes a system buffer and controls a physical state of the nonvolatile memory;
a battery which drives the nonvolatile memory and the controller;
first transmission/reception means capable of transmitting data in the nonvolatile memory to an outside and receiving data which is transmitted from the outside; and
second transmission/reception means capable of transmitting data in the nonvolatile memory to an outside and receiving data which is transmitted from the outside.

2. The device according to claim 1, wherein each of the first and second transmission/reception means is one of a USB terminal, an infrared port and a wireless LAN.

3. The device according to claim 1, wherein the nonvolatile memory includes a plurality of unit memory areas each having a data area and a redundant area, and
the protect information is stored in the redundant area.

4. The device according to claim 1, wherein the controller controls the nonvolatile memory, thereby to prevent data with the protect information, which is included in the data within the nonvolatile memory, from being transmitted from the first or second transmission/reception means.

5. The device according to claim 1, wherein the controller comprises:
an MPU which controls operations of the nonvolatile memory and the system buffer;
a first interface which is electrically connected to the first transmission/reception means; and
a second interface which is electrically connected to the second transmission/reception means.

6. The device according to claim 1, wherein the nonvolatile memory comprises a sense amplifier which reads out data from the nonvolatile memory.

7. The device according to claim 6, wherein the sense amplifier comprises a first data cache and a second data cache which are capable of storing the unit memory area.

8. The device according to claim 1, wherein the system buffer comprises a memory capable of storing the unit memory area.

9. The device according to claim 8, wherein the controller successively stores data of an exchanged said unit memory area in the memory, stores the data in the second data cache, stores the data in the first data cache, and writes the data in the nonvolatile memory, and, at the same time, successively reads out data of a to-be-next-exchanged said unit memory area from the nonvolatile memory, stores the data in the first data cache, stores the data in the second data cache, and stores the data in the memory.

10. The device according to claim 1, further comprising a switch which determines whether or not to execute data transfer or data exchange.

11. The device according to claim 1, further comprising an indicator which indicates to an outside that data transfer or data exchange is being executed.

12. A data transmission method for a semiconductor memory device comprising:
a first semiconductor memory device including a first nonvolatile memory which stores protect information, a first controller which includes a first system buffer and controls a physical state of the first nonvolatile memory, a battery which drives the first nonvolatile memory and the first controller, and first transmission/reception means capable of transmitting data in the first nonvolatile memory to an outside and receiving data which is transmitted from the outside, and second transmission/reception means capable of transmitting data in the first nonvolatile memory to an outside and receiving data which is transmitted from the outside; and
a second semiconductor memory device including a second nonvolatile memory, a second controller which includes a second system buffer and controls a physical state of the second nonvolatile memory, and third transmission/reception means capable of transmitting data in the second nonvolatile memory to an outside and receiving data which is transmitted from the outside, the data transmission method comprising:
electrically connecting one of the first transmission/reception means and the second transmission/reception means to the third transmission/reception means;
causing the first controller to read out transmission data from the first nonvolatile memory; and
causing the first controller not to transmit transmission data with the protection information, which is included in the transmission data, to the second semiconductor memory device.

13. The data transmission method according to claim 12, wherein the each of the first to third transmission/reception means is one of a USB terminal, an infrared port and a wireless LAN.

14. The data transmission method according to claim 12, wherein each of the first and second nonvolatile memories includes a plurality of unit memory areas each having a data area and a redundant area, and
the protect information is stored in the redundant area.

15. The data transmission method according to claim 12, wherein the first nonvolatile memory comprises a first sense amplifier which reads out data from the first nonvolatile memory, and the second nonvolatile memory comprises a second sense amplifier which reads out data from the second nonvolatile memory.

16. The data transmission method according to claim 12, wherein the first sense amplifier comprises a first data cache and a second data cache which are capable of storing the unit memory area, and
the second sense amplifier comprises a third data cache and a fourth data cache which are capable of storing the unit memory area.

17. The data transmission method according to claim 12, wherein the first controller comprises a first MPU which controls operations of the first nonvolatile memory and the first system buffer, a first interface which is electrically connected to the first transmission/reception means, and a second interface which is electrically connected to the second transmission/reception means, and
the second controller comprises a second MPU which controls operations of the second nonvolatile memory and the second system buffer, and a third interface which is electrically connected to the third transmission/reception means.

18. The data transmission method according to claim 12, wherein the first system buffer comprises a first memory capable of storing the unit memory area, and
the second system buffer comprises a second memory capable of storing the unit memory area.

19. The data transmission method according to claim 18, wherein after data of the unit memory area is exchanged from the second semiconductor memory device, the first controller executes:
storing the data of the exchanged unit memory area in the first memory, and at the same time reading out data of a to-be-next-exchanged said unit memory area from the first nonvolatile memory;
storing the data of the exchanged unit memory area in the second data cache and at the same time storing the data of the to-be-next-exchanged unit memory area in the first data cache;
storing the data of the exchanged unit memory area in the first data cache and at the same time storing the data of the to-be-next-exchanged unit memory area in the second data cache; and
writing the data of the exchanged unit memory area in the first nonvolatile memory and at the same time storing the data of the to-be-next-exchanged unit memory area in the first memory.

20. The data transmission method according to claim 12, wherein each of the first nonvolatile memory and the second nonvolatile memory is NAND-type flash memory.
